(19) United States
(12) Patent Application Publication
(10) Pub. No.: US 2010/0079961 A1
(43) Pub. Date: Apr. 1, 2010

(54) PRINTED CIRCUIT BOARD AND ELECTRONIC DEVICE

(75) Inventors: Yoshiaki Hiratsuka, Kawasaki (JP); Tatsuo Koizumi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/486,098

(22) Filed: Jun. 17, 2009

(30) Foreign Application Priority Data
Sep. 26, 2008 (JP) 2008-248568

(51) Int. Cl. H05K 5/00

(52) U.S. Cl. 361/752

(57) ABSTRACT

A printed circuit board includes an insulation layer and a wiring layer with a wiring pattern, which are alternately laminated; and a noise reduction element on a wiring between a connector and a wiring pattern in any one of wiring layers, wherein, when viewed from a surface of the printed circuit board, the wiring pattern includes an area overlapping with the wiring between the connector and the noise reduction element and does not overlap with a wiring pattern that does not include the area.

### CROSS-REFERENCE TO RELATED APPLICATION

This application is based upon and claims the benefit of priority of the prior Japanese Patent Application No. 2008-248568, filed on Sep. 26, 2008, the entire contents of which are incorporated herein by reference.

### FIELD

The embodiments discussed herein are related to a printed circuit board having a wiring pattern on its surface, in which an insulation layer made of an insulation material and a wiring layer made of a wiring pattern representing wiring are alternately laminated, and an electronic device equipped with such a printed circuit board.

### BACKGROUND

The advancement of industrial technology of today's world has brought about development of various kinds of electronic devices and there are many electronic devices having complicated structures. Especially in recent years, with the advancement of information society, technologies related to electronic devices for information processing such as computer rapidly advance, resulting in the increase of transmitting and receiving of information among electronic devices. There are many electronic devices that transmit and receive information to and from external electronic devices via an interface (I/F) cable for information communication. Generally in such electronic devices, an I/F connector that is to be engaged into a jack at the tip of an I/F cable is mounted on a printed circuit board on which surface a wiring pattern of an electronic circuit is formed.

In general, in an electronic device equipped with a printed circuit board, when electric signals are sent to a wiring pattern in the printed circuit board by the operation of the electronic device, sometimes subsidiary electric noise is generated. Especially, in an electronic device equipped with a printed circuit board mounted with an I/F connector, if such noise runs in a wiring pattern wired on the printed circuit board and reaches the I/F connector, sometimes an I/F cable connected to the I/F connector acts as antenna and thereby radiates radio noise around the electronic device. The radio noise is called radiation noise and causes radio disturbance when a radio receiver such as TV and radio receives radio waves. As a means for avoiding the generation of radiation noise, an element such as a common-mode choke coil, a ferrite bead, and a trance that has a property of reducing noise level of noise generated in an electric circuit may be disposed near the I/F connector on the printed circuit board, thereby reducing noise that runs in the wiring pattern on the surface of the printed circuit board and reaches the I/F connector (for example, see FIG. 2 of Japanese Laid-open Patent Publication No. 05-114439).

Incidentally, in recent years, to realize a downsized multifunctional electronic device, a small multifunctional printed circuit board is demanded and a multilayer printed circuit board in which a layer made of a wiring pattern and an insulation layer made of a resin material are alternately laminated has been increasingly used. In general, a printed circuit board having a large number of layers of wiring pattern provides a wider effective wiring area for an electric circuit and thereby serves as a multifunctional printed circuit board. In fact, among multilayer printed circuit boards available on the market, there is a highly multifunctional printed circuit board having as many as about 10 layers of wiring patterns. Generally, a noise reduction element is bulky and may be placed only on a wiring pattern in a surface layer. Therefore, if the above-described means for avoiding the generation of radiation noise is applied to the multilayer printed circuit board as it is, radiation noise is generated by noise that detours the noise reduction element on the surface and runs in a wiring pattern of an internal layer.

FIG. 1 illustrates a state in which radiation noise is generated in a printed circuit board 10_2 that is an example of a traditional multilayer printed circuit board.

The printed circuit board 10_2 in FIG. 1 is a multilayer printed circuit board having multiple internal layers made of wiring patterns as well as a wiring pattern 1 on its surface. FIG. 1 is a cross-sectional view of the printed circuit board 10_2. Hereafter, in order to distinguish between two types of wiring patterns, a wiring pattern provided on the surface of the printed circuit board 10_2 is referred to as a surface layer pattern 1 and a wiring pattern in internal layers of the printed circuit board 10_2 as an internal layer pattern 4.

A connector 3 is disposed at the end portion of the printed circuit board 10_2. In FIG. 1, the connector 3 and a jack (not illustrated) connected to the tip of an I/F cable 5 are engaged. In the printed circuit board 10_2 in FIG. 1, sometimes noise is generated by a circuit formed of an element disposed on the printed circuit board 10_2, the surface layer pattern 1, and the internal layer pattern 4, and the noise is propagated by a pattern where the noise is generated. In addition, although there is an insulator between the internal layer patterns 4 or between the internal layer pattern 4 and the surface layer pattern 1, since the noise is an AC pattern and acts as a capacitor of each pattern and an insulation layer, the noise is propagated to a pattern of another layer running along a certain pattern layer. The printed circuit board 10_2 in FIG. 1 is equipped with a noise reduction element 2 on the surface layer pattern 1. The noise running along the surface layer pattern 1 is reduced by the noise reduction element 2. The connector 3, because of its bulky size, is disposed on the surface layer of the printed circuit board 10_2. Therefore, seemingly, disposing the noise reduction element 2 on the surface layer pattern 1 can reduce the noise to the connector 3. However, as described above, since sometimes the noise propagates to the internal layer pattern 4, even if the noise reduction element 2 is disposed on the surface layer pattern 1, the noise still propagates to the connector 3 via the internal layer pattern 4.

Such noise is radiated as radio noise from the I/F cable 5 and causes the above-described radio disturbance problem. Therefore, it is impossible to avoid the radio disturbance problem caused by the radiation noise in the multilayer printed circuit board simply disposed with the noise reduction element on its surface layer pattern like the multilayer printed circuit board 10_2 of FIG. 1.

It is conceivable to incorporate the noise reduction element 2 within the connector 3 as a workaround for this problem (for example, see FIG. 1 of Japanese Laid-open Patent Publication No. 05-114439). However, this method requires a large connector incorporating a noise reduction element, which is not suitable for realizing a downsized multifunctional printed circuit board.

Conventionally, in manufacturing stage of the multilayer printed circuit board, a route that allows noise to detour around a noise reduction element to move to a connector is eliminated in the multilayer printed circuit board. This is realized by not forming an internal layer pattern inside the printed circuit board in an area that overlaps in a plane view with an area in the surface layer pattern that extends and has a portion connecting a noise reduction element and a connector thereon.

FIG. 2 illustrates an example of a multilayer printed circuit board without a route of allowing noise to detour around the noise reduction element 2 to move to the connector 3.

A printed circuit board 10_1 of FIG. 2 is a multilayer printed circuit board in which a wiring pattern is formed. FIG. 2 illustrates a cross-sectional view of the printed circuit board 10_1. In the printed circuit board 10_1 of FIG. 2, between the noise reduction element 2 and the connector 3 located at the end portion of the printed circuit board 10_1, although the surface layer pattern 1 exists for the purpose of electrically connecting various kinds of circuits formed on the printed circuit board 10_1 and the connector 3, there is provided a no pattern area 6 in which the internal layer pattern 4 is not formed. Because of the no pattern area 6, the noise propagated in the internal layer pattern 4 in the right direction of FIG. 2 to the underside of the noise reduction element 2 may not propagate any further in the right direction. As a result of this, the noise is prevented from reaching the connector 3, thereby avoiding the generation of radio disturbance due to the radiation noise in the printed circuit board 10_1 of FIG. 2.

As described above, in the field of printed circuit board, demand for a downsized multifunctional printed circuit board is ever increasing and a printed circuit board formed of many layers greater than 20 layers of internal layer patterns may be eventually required. However, there is a concern related to thickness as follows. The thickness of the no pattern area is thinner than that of a portion where the internal layer pattern exists by the thickness of the internal layer pattern. The thickness may not pose a big problem in a multilayer circuit board formed of a few layers. However, in a printed circuit board formed of many layers greater than 20 layers of internal layer patterns, a difference of the thickness becomes quite large. In a printed circuit board that lacks flatness is prone to cause a warp in the surface layer pattern at the end portion of the printed circuit board when external force such as vibration is applied to the printed circuit board. The warped surface layer pattern may be detached from the printed circuit board, eventually causing a break in an electric circuit. Because of this, to avoid the generation of radio disturbance by radiation noise in the multilayer printed circuit board, a new solution is required other than providing the no pattern area illustrated in FIG. 2.

### SUMMARY

According to an aspect of the invention, the printed circuit board including:

an insulation layer and a wiring layer with a wiring pattern, which are alternately laminated; and

a noise reduction element on a wiring between a connector and a wiring pattern in any one of wiring layers,

wherein, when viewed from a surface of the printed circuit board, the wiring pattern includes an area overlapping with the wiring between the connector and the noise reduction element and does not overlap with a wiring pattern that does not include the area.

According to the printed circuit board described above, at least in a wiring layer among wiring patterns of internal wiring layers, a wiring pattern that exists in an area extending from a disposed position of a noise reduction element to a disposed position of a connector, in a plane view, is insulated from the rest of wiring patterns in the same internal wiring layer. This makes it difficult for noise to move from the rest of wiring patterns to the wiring pattern in the area. As a result, in the printed circuit board, the noise hardly moves to the wiring pattern on the surface of the printed circuit board by detouring around the noise reduction element to reach the connector, thereby avoiding the generation of the radiation noise.

Although the wiring pattern in the above-described area is insulated from the rest of wiring patterns in the wiring layer, the wiring pattern is of a same type as the rest of wiring patterns, thereby a large difference in the thickness between an overlapping area and another area is not made in the printed circuit board. In this way, in the printed circuit board, it is possible to avoid detachment of the wiring pattern on the surface of the printed circuit board from the printed circuit board due to a difference in the thickness of the printed circuit board.

Further, according to another aspect of the invention, the electronic device including a printed circuit board,

the printed circuit board including:

an insulation layer and a wiring layer with a wiring pattern, which are alternately laminated, and

a noise reduction element on a wiring between a connector and a wiring pattern in any one of wiring layers,

wherein, when viewed from a surface of the printed circuit board, the wiring pattern includes an area overlapping with the wiring between the connector and the noise reduction element and does not overlap with a wiring pattern that does not include the area.

The electronic device described above includes the above-described printed circuit board. Therefore, in the electronic device, the generation of radiation noise from the printed circuit board is prevented as well as inconveniences due to the detachment of the wiring pattern in the printed circuit board is avoided.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a state in which radiation noise is generated in a printed circuit board that is an example of a multilayer printed circuit board;

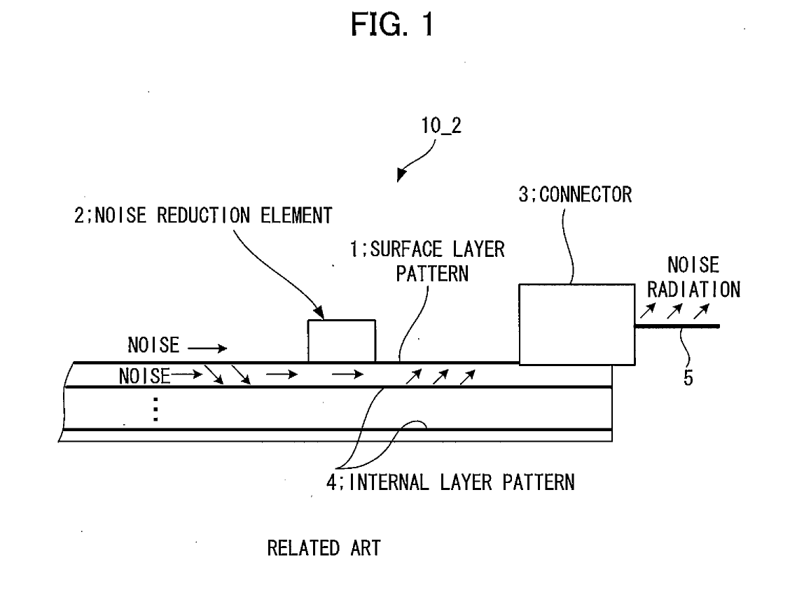

FIG. 2 illustrates an example of a multilayer printed circuit board without a route that allows noise to detour around a noise reduction element to move to an I/F connector;

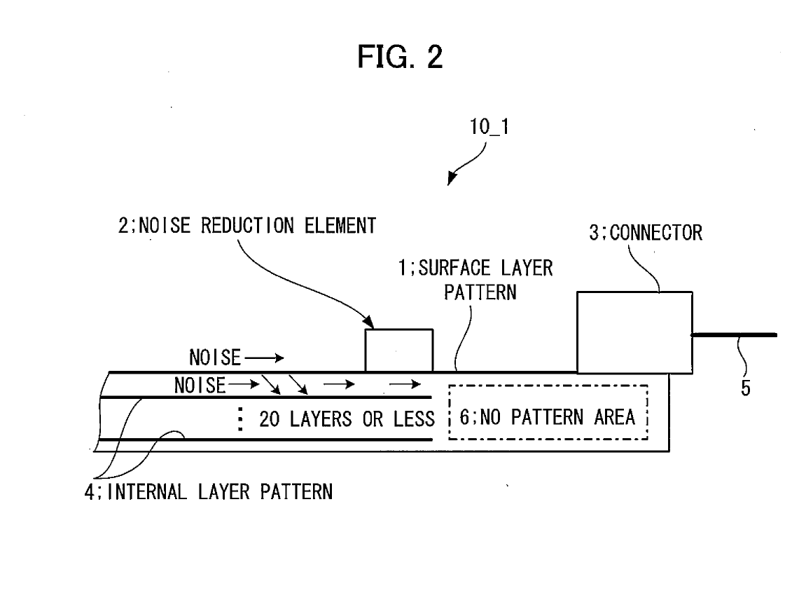

FIG. 3 illustrates an electronic device employing a printed circuit board that is an embodiment of the printed circuit board;

FIG. 4 illustrates an I/F connector disposed on the printed circuit board, together with a jack into which the I/F connector is engaged;

FIG. 5 illustrates a structure of the I/F connector;

FIG. 6 is a cross-sectional view of a printed circuit board;

FIG. 7 illustrates a wiring pattern inside the printed circuit board, at the end portion of the printed circuit board when the printed circuit board in FIG. 6 is viewed from above; and

FIG. 8 is a cross-sectional view of a printed circuit board of another embodiment.

### DESCRIPTION OF EMBODIMENTS

Specific embodiments of the printed circuit board and the electronic device explained will be described below referring to the drawings.

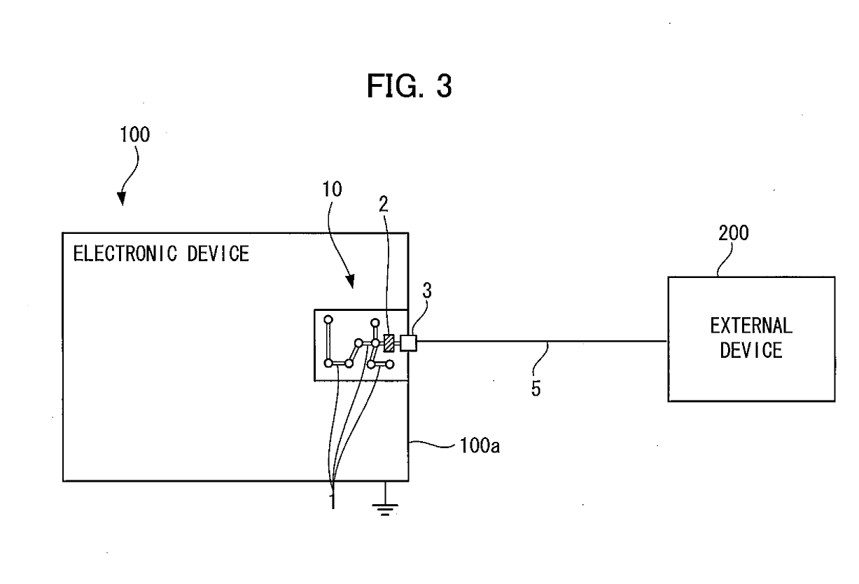

FIG. 3 illustrates an electronic device 100 employing a printed circuit board 10 that is an embodiment of the printed circuit board.

The electronic device 100 is connected to an external device 200 via an interface (I/F) cable 5. The electronic device 100 transmits and receives information to and from the external device 200 via the I/F cable 5. The electronic device 100 is typified by a computer. The external device 200 is typified by another computer, or a printer. The I/F cable 5 is typified by a LAN (Local Area Network) cable. A housing 100a of the electronic device 100 is made of an electrically conducting metallic material. As illustrated in FIG. 3, the housing 100a is grounded and the potential of the housing 100a is kept to the ground (zero potential).

The electronic device 100 is equipped with a printed circuit board 10, and a wiring pattern 1 is formed on a surface of the printed circuit board 10. As will be described later, the printed circuit board 10 is a multilayer printed circuit board in which a wiring pattern is also formed in the inside. FIG. 3 illustrates the wiring pattern 1 on the surface of the printed circuit board 10. Hereafter, the wiring pattern 1 on the surface of the printed circuit board 10 is referred to as a surface layer pattern 1 to distinguish it from a wiring pattern of an internal layer in the printed circuit board 10.

On the surface of the end portion of the printed circuit board 10, an I/F connector that engages into a jack connected at the tip of the I/F cable 5 is disposed, and the I/F connector is connected to the surface layer pattern 1 on the surface of the printed circuit board 10. FIG. 3 illustrates a whole of the jack and the I/F connector engaged into the jack as a connector 3. Also, on the surface of the printed circuit board 10, at a position near the connector 3 (i.e., a position in the proximity of the I/F connector), a noise reduction element 2 is disposed. The noise reduction element 2 attenuates noise level of noise running in the surface layer pattern 1 to the connector 3, thereby reducing noise reaching the connector 3. As the reduction element 2, for example, a common-mode choke coil, a ferrite bead, and a trance may be employed. Additionally, on the surface of the printed circuit board 10, although various kinds of electric elements forming an electric circuit other than the noise reduction element 2 are disposed, they are not illustrated in FIG. 3.

Next, the I/F connector included in the printed circuit board 10 in FIG. 3 will be explained.

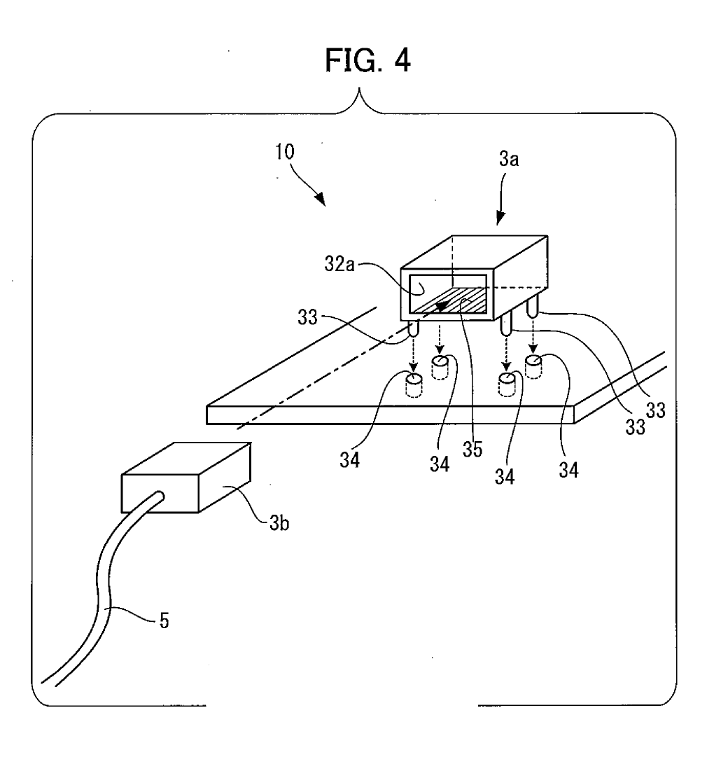

FIG. 4 illustrates an I/F connector 3a included in the printed circuit board, together with a jack 3b into which the I/F connector is engaged.

The I/F connector 3a is equipped with multiple U-shaped electrically conductive metal wires 33 on the undersurface. The U-shaped portions of the metal wires 33 protrude downward in FIG. 4, and the protruding metal wires 33 are inserted into holes 34 disposed on the surface of the printed circuit board 10 in the direction indicated by an arrow of a dotted line and soldered, thereby securely attaching the I/F connector 3a to the printed circuit board 10. An opening 32a is formed in the I/F connector 3a, and on the wall of the opening 32a, multiple lead wires 35 are disposed. When the jack 3b connected at the tip of the I/F cable 5 is inserted into the opening 32a from the direction of a dashed line in FIG. 4, the I/F connector 3a and the jack 3b are engaged. In a state where the I/F connector 3a and the jack 3b are engaged, the lead wires 35 inside the I/F connector 3a are conductive with the I/F cable 5. In this conductive state, transmitting and receiving of electric signals representing information is performed between the electronic device 100 and the external device 200 in FIG. 3.

Next, the structure of the I/F connector 3a will be explained.

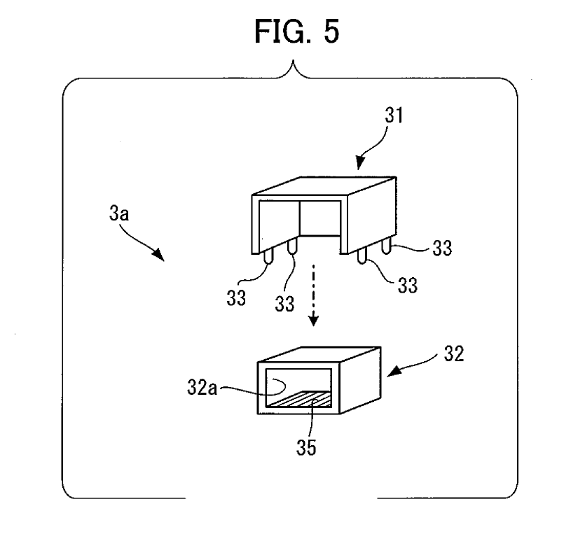

FIG. 5 illustrates the structure of the I/F connector 3a.

The I/F connector 3a has a structure such that a lead wire holding section 32 for holding the lead wires 35 is covered with an outer section 31 from the direction of a dashed line in FIG. 5. On the undersurface of the outer section 31, the above-described metallic wires 33 are attached, and a whole of the outer section 31 is formed of a conductive metallic material including the metallic wires 33. The lead wire holding 32 has the above-described opening 32a and holds the lead wires 35 on the wall of the opening 32a. The lead wire holding section 32 is made of an insulating plastic material, and therefore, even in a state where the lead wire holding section 32 is covered with the outer section 31, the lead wires 35 and the outer section 31 are electrically insulated from each other.

Next, the internal structure of the printed circuit board 10 will be explained.

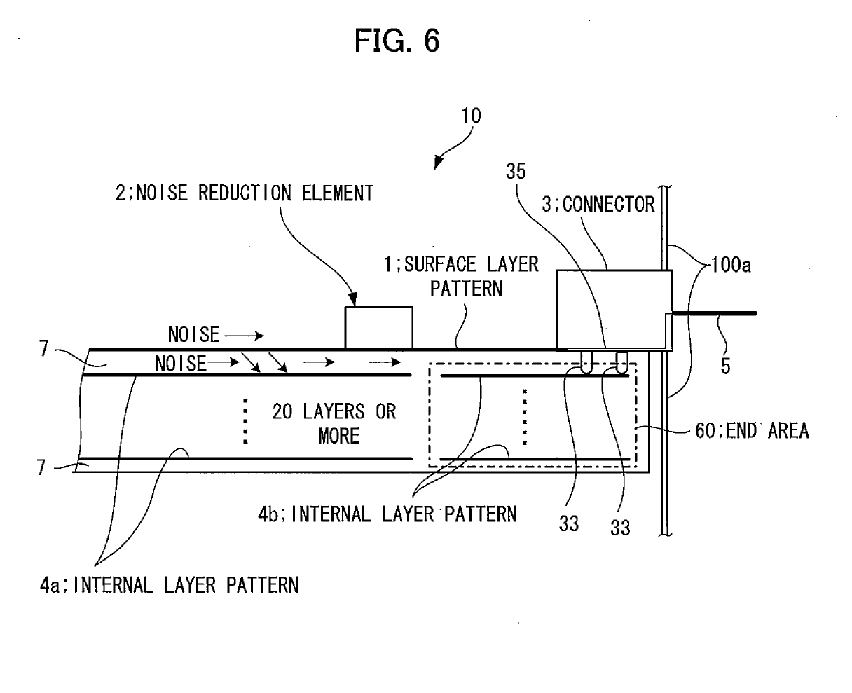

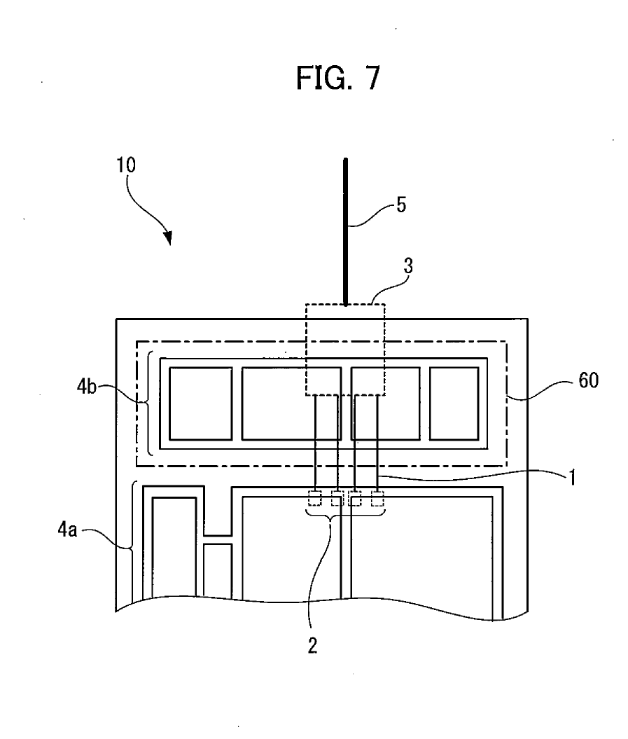

FIG. 6 is a cross-sectional view of the printed circuit board 10. FIG. 7 illustrates a wiring pattern inside the printed circuit board 10, at the end portion of the printed circuit board 10 when the printed circuit board 10 in FIG. 6 is viewed from above.

As described above, the printed circuit board 10 includes, in addition to the surface layer pattern 1 that is disposed on the surface of the printed circuit board 10 and is a wiring pattern for connecting a filter 2 and the connector 3, a layer made of a wiring pattern inside the printed circuit board 10. Hereafter, wiring patterns inside the printed circuit board 10 are referred to as internal layer patterns 4a, 4b. In FIG. 6, on the bottom of the surface layer pattern 1, multiple internal layer patterns 4a, 4b extending along the surface layer pattern 1 are illustrated. In between the internal layer patterns 4a, 4b and the surface layer pattern 1, a layer formed of an insulating resin material 7 is disposed. The printed circuit board 10 includes 20 and more layers made of the internal layer patterns 4a, 4b in all, and is a highly multifunctional printed circuit board providing a wide effective area for the wiring of an electric circuit. As described above, the I/F connector 3a is disposed at the end portion of the printed circuit board 10 (See FIG. 4). In FIGS. 6 and 7, a whole of the jack 3b (See FIG. 4) and the I/F connector 3a engaged into the jack 3b that is connected at the tip of the I/F cable 5 is illustrated as the connector 3. In a state where the I/F connector 3a and the jack 3b are engaged, the lead wires 35 inside the connector 3 (to be precise, inside the I/F connector 3a) are connected to the surface layer pattern 1 and the I/F cable 5 as illustrated in FIG. 6.

Also in the printed circuit board 10 in FIGS. 6 and 7, sometimes noise may be caused by an electric circuit formed of an electric component disposed on the printed circuit board 10, the surface layer pattern 1, and the internal layer pattern 4a.

As described above, in the printed circuit board 10 in FIG. 6, the noise reduction element 2 is disposed in the position near the I/F connector 3 on the surface layer pattern 1, thereby the noise that runs along the surface layer pattern 1 in the direction of a rightward arrow in FIG. 6 to the position of the noise reduction element 2 is subjected to the attenuation of noise level by the noise reduction element 2.

On the other hand, some noise that propagates along the internal layer pattern 4a in the direction of the connector 3 or some noise that propagates along the internal layer pattern 4a after being generated in the surface layer pattern 1 reach underneath the noise reduction element 2. However, since it may not be possible to place the noise reduction element 2 on the internal layer side, noise level may not be attenuated. Here, in the internal layer of the printed circuit board 10, as illustrated in FIG. 7, the internal layer pattern 4b present in an end area 60 is insulated from the internal layer pattern 4a present in another area. The cross-sectional view of FIG. 6 illustrates a state of no conductivity between the respective internal layer patterns 4b and the respective internal layer patterns 4a present on the left side of the drawing, by being isolated from each other. The respective internal layer patterns 4b exists in the end area 60 enclosed by a dashed line, which is located under the connector 3 and the surface layer pattern 1 connecting the noise reduction element 2 and the connector 3. In the printed circuit board 10, the internal layer pattern 4a outside the end area 60 is a pattern that acts as wiring of the electric circuit. It is desirable that the respective internal layer patterns 4b in the end area 60 be an isolated pattern without having a function of wiring of the electric circuit.

The propagation of noise across layers is influenced by the size of an overlapping area of wiring patterns of each layer. In the present embodiment, since all the internal layer patterns 4b in the end area 60 is insulated from all the internal layer patterns 4b, any one of the internal layer patterns does not overlap with the internal layer patterns 4a for forming an electric circuit. That is, no propagation of noise occurs from the internal layer pattern 4a to the internal layer pattern 4b. In addition, since the noise in the surface layer pattern 1 between the noise reduction element 2 and the connector 3 is reduced by the noise reduction element 2, there is no propagation of noise to the connector 3 through the surface layer pattern 1.

In this way, the noise propagation to the connector 3 may be prevented.

Each of the internal layer patterns 4b in the end area 60 maybe an isolated solid pattern or one in which isolated small patterns are scattered.

Moreover, since the wiring patterns 4b are provided in the area, no difference due to the presence and absence of a wiring pattern is made in the thickness of the printed circuit board. Therefore, it is possible to prevent a wiring pattern on the surface from being detached from the printed circuit board due to the difference in the thickness of the printed circuit board.

Here, as illustrated in FIG. 6, metal wires 33 connected to the outer section 31 (not illustrated in FIG. 6, see FIG. 5) that is an outer portion of the connector 3 may be connected to one of the internal layer patterns 4b that is the nearest to the surface layer pattern 1. Furthermore, as illustrated in FIG. 6, an outer portion of the connector 3 (i.e., the outer section 31 in FIG. 5) is in contact with the housing 100a of the electronic device 100 (not illustrated in FIG. 6, see FIG. 3). The housing 100a is made of a conductive metallic material and grounded, as stated above in the explanation of FIG. 3. By this structure, even if noise reaches the connector 3, radiated noise hardly occurs.

Moreover, in the printed circuit board 10, since the connector 3 is present at the edge portion of the printed circuit board 10 as illustrated in FIG. 6, and the noise reduction element 2 is present at a position close to the connector 3, there is no need to secure very large area to include an isolated internal layer pattern therein. Therefore, it is possible to avoid such a situation that wiring area of an electric circuit is largely reduced due to the disposition of an isolated internal layer pattern in the printed circuit board 10.

Next, another embodiment that is different from the above-described embodiment will be described below.

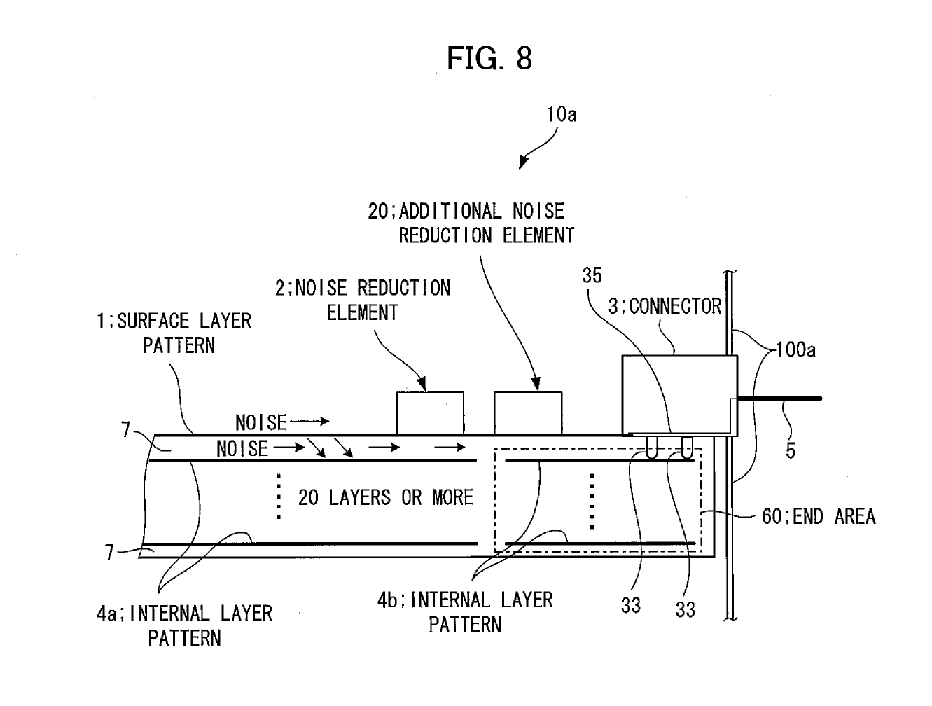

FIG. 8 is a section view of a printed circuit board 10a of another embodiment.

In the printed circuit board 10a of FIG. 8, same numerals are given to the elements that are same as those in the printed circuit board 10 of FIG. 6, and redundant explanation about the same elements is omitted. The printed circuit board 10a of FIG. 8 is different from the printed circuit board 10 of FIG. 6 on the point that the printed circuit board 10a is further quipped with an additional noise reduction element 20 and thus includes two noise reduction elements in total. Except this point, the printed circuit board 10a of FIG. 8 has the same structure as that of the printed circuit board 10 of FIG. 6. In the following, explanation is focused on this different point.

In the printed circuit board 10a of FIG. 8, noise running along the surface layer pattern 1 in the direction of the rightward arrow to the position of the noise reduction element 2 on the left side of FIG. 8 is subjected to attenuation of nose level by the noise reduction element 2 on the left side of FIG. 8, and its noise level becomes approximately zero when the noise reaches the connector 3, as stated above in the explanation of FIG. 6.

Also in the printed circuit board 10a of FIG. 8, since the isolated internal layer pattern 4b exists in the end area 60, the noise running in the internal layer pattern 4a in the rightward direction in FIG. 8 to reach the underside of the noise reduction element 2 hardly moves further in the rightward direction, and eventually there is an extremely small amount of noise that can move to the surface layer pattern 1. Here, in the printed circuit board 10a of FIG. 8, the additional noise reduction element 20 is connected to the surface layer pattern 1 connecting the noise reduction element 2 on the left side and the connector 3. Thereby, an extremely small amount of noise that has moved to the surface layer pattern 1 is subjected to attenuation of noise level by the added noise reduction element 20 when the noise runs in the surface layer pattern 1 to the position of the added noise reduction element 20. As a result of this, in the printed circuit board 10a of FIG. 8, it is possible to suppress noise from reaching the connector 3 more securely.

In the above embodiments, there are two or fewer noise reduction elements. However, three and more noise reduction elements may be disposed in order to further prevent noise from reaching the I/F connector 3 in the above-described printed circuit board and the electronic device.

Also, in the above explanation, the outer portion of the connector 3 (i.e., the outer section 31 of FIG. 5) has directly made into contact with the housing 100a. However, in the printed circuit board and the electronic device, the outer section 31 of FIG. 5 may be conductive with the housing 100a via another conductive member.

Further, in the above-explained two embodiments, the noise reduction element 2 is connected to the surface layer pattern 1. However, in the printed circuit board and the electronic device, the noise reduction element 2 maybe connected to the internal layer pattern 4a via a layer made of a resin material 7. For example, the noise reduction element 2 may be connected to the nearest internal layer pattern 4a to the surface layer pattern 1.

On the basis of the above-explained two embodiments, various kinds of preferable modes of the printed circuit board will be described.

In the printed circuit board, it is preferable that “in all the wiring layers of the printed circuit board, a wiring pattern in an area from the disposing position of the connector to the disposing position of the noise reduction element on the printed circuit board is not electrically connected to an internal layer pattern in another area”.

According to this preferable mode, reaching of noise to the connector 3 is more securely suppressed. In the wiring patterns of all the internal layers of the printed circuit board 10 of FIG. 6 and the printed circuit board 10a of FIG. 8, the internal layer pattern 4b in the end area 60 is insulated from the internal layer pattern 4a outside the end area 60.

Also, in the printed circuit board, “the connector may be placed on the printed circuit board” or, “the connector may be connected to a metallic outer housing”.

Furthermore, in the printed circuit board, it is preferable that “the printed circuit board further includes an area used to place a second noise reduction element independent of the noise reduction element serving as a first noise reduction element, the second noise reduction element being connected to a wiring pattern that connects the first noise reduction element and the connector, and reducing noise running in the wiring pattern to the connector”.

According to this preferable mode, even if there is noise that runs by detouring around the first noise reduction element, the noise is reduced by the second noise reduction element, thereby more surely preventing noise from reaching the connector. In the printed circuit board 10a of FIG. 8, the additional noise reduction element 20 is connected to the surface layer pattern 1 that connects the noise reduction element 2 on the left side and the connector 3, thereby realizing a preferable mode equipped with the second noise reduction element.

Additionally, in the printed circuit board, it is preferable that “the printed circuit board is equipped in an electronic device having a grounded electrically-conductive housing, and the connector covers a lead wire connected to a wiring pattern on the surface of the printed circuit board, an insulating metal wire holding section for holing the lead wire, and a lead wire holding section as well as the connector includes a conductive outer section connected to a wiring pattern in a wiring layer that is the nearest to the surface among the internal wiring layers”.

According to this preferable mode, even if noise moves to the wiring pattern in the nearest wiring layer, the noise runs in the outer section and the housing in this order, instead of being discharged in the surroundings from the connector, and is finally absorbed in the ground, thereby realizing a printed circuit board in which radiated noise is hardly generated. In the printed circuit board 10 of FIG. 6 and the printed circuit board 10a of FIG. 8, the metal wire 33 connected to the outer section 31 (not illustrated in FIG. 6, see FIG. 5) that is an outer portion of the connector 3 is connected to the nearest internal layer pattern 4b to the surface layer pattern 1 among the multiple internal layer patterns 4b. The outer portion of the connector 3 (i.e., the outer section 31 in FIG. 5) is conductive and in contact with the grounded conductive housing 100a as illustrated in FIGS. 6, 8. In this way, in the two embodiments, the above-described preferable mode is realized. Here, in these embodiments, the lead wire 35 exemplifies the lead wire in the preferable mode, the lead wire holding section 32 exemplifies the lead wire holding section in the preferable mode. In addition, a combination of the outer section 31 and the metal wire 33 exemplifies the outer section in the preferable mode.

Moreover, in the printed circuit board, it is preferable that “the connector is disposed at the end portion of the printed circuit board and the noise reduction element is disposed in a position close to the connector”.

According to this preferable mode, there is no need to secure very large area for a wiring pattern insulated from rest of the wiring pattern of an internal layer, and thus avoiding a situation in which wiring area of an electric circuit is reduced largely by providing the insulated wiring pattern. In either of the printed circuit board 10 of FIG. 6 and the printed circuit board 10a of FIG. 8, the I/F connector 3 is disposed at the edge portion of the respective printed circuit boards, and the noise reduction element 2 is disposed in a position close to the I/F connector 3. Thus, in the two embodiments, the preferable mode in which the connector is disposed at the end portion of the printed circuit board is realized.

According to the above-described printed circuit board, it is possible to avoid the generation of radiation noise and to maintain flatness.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention has been described in detail, it should be understood that the various changes, substitutions, and alterations could be made hereto without departing from the spirit and scope of the invention.

What is claimed is:

1. A printed circuit board, comprising:
an insulation layer and a wiring layer with a wiring pattern, which are alternately laminated; and
a noise reduction element on a wiring between a connector and a wiring pattern in any one of wiring layers,
wherein, when viewed from a surface of the printed circuit board, the wiring pattern includes an area overlapping with the wiring between the connector and the noise reduction element and does not overlap with a wiring pattern that does not include the area.

2. The printed circuit board according to claim 1, wherein the wiring pattern including the area that overlaps with the wiring between the connector and the noise reduction element does not overlap with all the wiring patterns in all the wiring layers that do not include the area.

3. The printed circuit board according to claim 1, wherein the connector is placed on the printed circuit board.

4. The printed circuit board according to claim 1, wherein the connector is connected to a metallic outer housing.

5. The printed circuit board according to claim 2, wherein the connector is connected to a metallic outer housing.

6. The printed circuit board according to claim 3, wherein the connector is connected to a metallic outer housing.

7. The printed circuit board according to claim 1, further comprising an area used to place a second noise reduction element independent of the noise reduction element serving as a first noise reduction element, the second noise reduction element being connected to a wiring pattern that connects the first noise reduction element and the connector, and reducing noise running in the wiring pattern to the connector.

8. An electronic device including a printed circuit board,
the printed circuit board comprising:
an insulation layer and a wiring layer with a wiring pattern, which are alternately laminated, and
a noise reduction element on a wiring between a connector and a wiring pattern in any one of wiring layers,
wherein, when viewed from a surface of the printed circuit board, the wiring pattern includes an area overlapping with the wiring between the connector and the noise reduction element and does not overlap with a wiring pattern that does not include the area.

9. The electronic device according to claim 8, wherein the wiring pattern including the area that overlaps with the wiring between the connector and the noise reduction element does not overlap with all the wiring patterns in all the wiring layers that do not include the area.

10. The electronic device according to claim 8, wherein in the printed circuit board, the connector is placed on the printed circuit board.

11. The electronic device according to claim 8, wherein in the printed circuit board, the connector is connected to a metallic outer housing.

12. The electronic device according to claim 9, wherein in the printed circuit board, the connector is connected to a metallic outer housing.

13. The electronic device according to claim 10, wherein in the printed circuit board, the connector is connected to a metallic outer housing.

14. The electronic device according to claim 8, wherein the printed circuit board further comprises an area used to place a second noise reduction element independent of the noise reduction element serving as a first noise reduction element, the second noise reduction element being connected to a wiring pattern that connects the first noise reduction element and the connector, and reducing noise running in the wiring pattern to the connector.
